(19) United States
(12) Patent Application Publication
(10) Pub. No.: US 2006/0157699 A1
(43) Pub. Date: Jul. 20, 2006

(54) Test structure for integrated electronic circuits

(75) Inventors: Michel Vallet, Vaulnaveys Le Haut (FR); Philippe Sardin, Saint Isnier (FR); Thierry Parrassin, Grenoble (FR); Sylvain Dudit, Grenoble (FR)

Correspondence Address: SEED INTELLECTUAL PROPERTY LAW GROUP PLLC, 701 FIFTH AVENUE, SUITE 6300, SEATTLE, WA, 98104-7092, US

(73) Assignee: STMicroelectronics SA, Montrouge (FR)

(21) Appl. No.: 11/302,409

(22) Filed: Dec. 12, 2005

(30) Foreign Application Priority Data
Dec. 14, 2004 (FR) 0413292

(51) Int. Cl. H01L 23/58

(52) U.S. Cl. 257/48

(57) ABSTRACT

A test structure for integrated electronic circuits having a substantially planar substrate coated with a plurality of metallization layers comprises a switching element formed on the surface of the substrate. It also comprises a tunnel formed in one or more metallization layers between the top of the switching element and the front side of the integrated circuit. This tunnel is designed to channel photons emitted by the switching element towards the front side.

### BACKGROUND OF THE INVENTION

1. Field of the Invention

The present invention generally relates to test structures for integrated electronic circuits. More particularly, it relates to diagnostic techniques and failure analysis for integrated circuits based on photon emission.

2. Description of the Related Art

All these techniques are based on the same principle. The electric field existing across the space-charge region of transistors of the FET (Field Effect Transistor) type, under saturation conditions, accelerates the minority carriers, for example electrons in an n-FET. The carriers acquire enough energy to generate photons, in other words light.

In CMOS (Complementary Metal-Oxide Semiconductor) technology, saturation of the transistors occurs briefly during switching, and relates especially to n-MOS transistors (MOS transistors of the n type). For this reason, the acquisition of the photons emitted by a semiconductor device using CMOS technology operating at high switching speeds yields information on the operational timing of the device.

Current techniques use test structures comprising a switching element with one transistor, for example an n-MOS transistor, implanted within the areas of the integrated circuit that it is desired to characterize. A typical example is the measurement of the access time to a memory, for which such a switching element is placed close to the output of the memory. The transistor of the element is made accessible from the outside, so as to be able to power it and control its switching. The test using optical imaging is carried out on the front side of the integrated circuit by means of an acquisition device such as an SSPD (Super-conducting Single-element Photon Detector) sensor or equivalent.

The measurement time on a transistor is however relatively long, around 5 mn. It has been identified that this length of time comes from the existence of evanescent photons emitted by neighboring transistors which interfere with the measurement on the transistor in question.

### BRIEF SUMMARY OF THE INVENTION

One embodiment of the invention improves the signal-to-noise ratio of the photon measurement, in order to reduce the acquisition time.

The document FR-A-2 771 853 divulges a test pin surrounded by a first metallic ring formed within a surface metallization layer and by a second ring formed within a lower metallization layer, these rings being electrically interconnected by at least one via and being set at a fixed potential. This structure yields good results for a measurement by electron beam, but is not suitable for a measurement based on photon emission.

One embodiment of the invention proposes the addition of a tunnel above the transistor under test, so as, on the one hand, to focus the photons emitted by the transistor concerned and, on the other, to serve as a screen from the evanescent photons emitted by the neighboring transistors.

More particularly, one aspect of the present invention is a test structure for integrated electronic circuits having a substantially plane substrate coated with a plurality of metallization layers, which test structure comprises a switching element formed on the surface of the substrate. The test structure is noteworthy in that it also comprises a tunnel formed between the top of the switching element and the front side of the integrated circuit. The tunnel comprises a stack of metal rings, adjacent rings being connected to one another by vias. These metal rings are formed within respective metallization layers coating the substrate of the integrated circuit. Such a tunnel is designed to channel photons emitted by the switching element towards the front side of the integrated circuit by the fact that the density and the distribution of the vias are such that they provide a screen preventing the photons from escaping from the tunnel between two adjacent stacked metal rings.

The tunnel not only guides the photons emitted by the switching element towards the active surface of an acquisition device disposed substantially in line with the switching element, but also prevents any evanescent photons coming from neighboring transistors from interfering with the measurement. Thus, the signal-to-noise ratio of the photon measurement for the acquisition device is improved. The measurement time for the switching element can thus be reduced.

Another advantage is that it allows the test structure to be easily reparable from the front side of the integrated circuit. Hence, the installation, whether manual or automated, of the acquisition device in line with the test structure can also be achieved more quickly.

In general, the first metallization layer (the layer closest to the substrate) is reserved for the fabrication of the connections that lead to the active regions or to the transistor gate regions. The first metallization layer is used for the formation of the connections, and the others for the formation of the tunnel. However, the tunnel may also comprise a metal ring within the first metallization layer, in which the passage of the metallic connections for the power supply and control of the switching element is provided. In practice, current integrated circuit fabrication technologies allow the number of metallization layers to reach, for example, eight or nine stacked layers that are insulated from one another by layers of silicon dioxide (SiO₂). In all cases, the tunnel comprises metal rings within respective metallization layers, where two adjacent stacked rings are connected by vias. The density and the distribution of the vias are such that they provide a screen preventing the photons from escaping from the tunnel between two adjacent stacked metal rings. This precaution also prevents evanescent photons from entering the tunnel from the outside.

In one preferred embodiment, the metal rings are substantially concentric, with axes substantially orthogonal to the substrate surface. Normally, this is the simplest solution. However, tilting the axis of the tunnel from the perpendicular to the substrate surface can also be envisaged, for example in order to make the photons exit from the front side of the integrated circuit in a laterally displaced area.

In practice, it is not currently possible to push the vias much closer together, for reasons associated with their fabrication process. For this reason, advantageously, a plurality of vias connecting two adjacent stacked metal rings can comprise a first group of vias disposed around an inner ring and a second group of vias disposed around an outer ring. These rings have substantially the same shape as the metal rings. The vias of the inner ring are laterally spaced from one another by a distance that is less than a corresponding characteristic dimension of the cross section of the vias in a plane orthogonal to the axis of the tunnel; similarly, the vias of the outer ring are laterally spaced from one another by a distance that is less than a corresponding characteristic dimension of the cross section of the vias in a plane orthogonal to the axis of the tunnel; in addition, the vias of the inner ring and the vias of the outer ring are disposed staggered with respect to one other. In this way, an optical screen that blocks the photons is obtained.

In one preferred embodiment, the distance between the alignment direction of the vias (considered at the center of the vias) of the inner ring and that of the vias of the outer ring is of the order of a corresponding characteristic dimension of the cross section of the said vias in a plane orthogonal to the axis of the tunnel. Reflection and/or diffraction phenomena, which could lead to the passage of photons through the vias, are thus minimized.

In one embodiment, the metal ring formed within the surface metallization layer protrudes with respect to the projection, in the plane of the said layer, of the metal rings formed within the underlying metallization layers. Thus, although it is preferable to minimize the width of the metal rings, the ring formed within the surface metallization layer allows the active surface of the acquisition device to be protected from the evanescent photons.

Another aspect of the invention relates to an integrated electronic circuit comprising a test structure such as is defined hereinabove. In particular, it can relate to a circuit fabricated using SOI (Silicon on Insulator) technology, for which the invention provides particularly good results. For example, it can be applied to a memory of the MRAM or Flash type for which electron beam measurement techniques may not be envisaged and, more generally, to any electronic circuit using CMOS technology operating in a low-power consumption regime (hence with a low power supply voltage, for example 1.1 V).

### BRIEF DESCRIPTION OF THE SEVERAL VIEWS OF THE DRAWING(S)

Other features and advantages of the invention will become apparent upon reading the description that follows. This is purely illustrative and must be read with regard to the appended drawings in which:

FIG. 1 is a top view of a CMOS inverter;

FIG. 2 is a cross-sectional view of a test structure comprising a CMOS inverter as switching element, illustrating the principle of the photon measurement by a conventional acquisition device;

FIGS. 3 and 4 are graphs of a control signal and of an acquisition signal, respectively, for the photon measurement according to FIG. 2;

FIGS. 5 and 6 are graphs of a control signal and of an acquisition signal, respectively, for the photon measurement by a test structure comprising a buffer circuit in place of an inverter as switching element;

FIG. 7 is a three-dimensional view of an example of a photon tunnel forming part of a test structure according to the present invention;

FIG. 8 is a cross-sectional view of an example of a test structure according to the present invention, incorporating a photon tunnel according to FIG. 7;

FIG. 9 is a view of the test structure according to one embodiment of the present invention, in a cross section within the plane of the metal ring of the photon tunnel that is the closest to the substrate of the integrated circuit, and

FIG. 10 is a partial three-dimensional view of one embodiment of an integrated electronic circuit according to the invention.

### DETAILED DESCRIPTION OF THE INVENTION

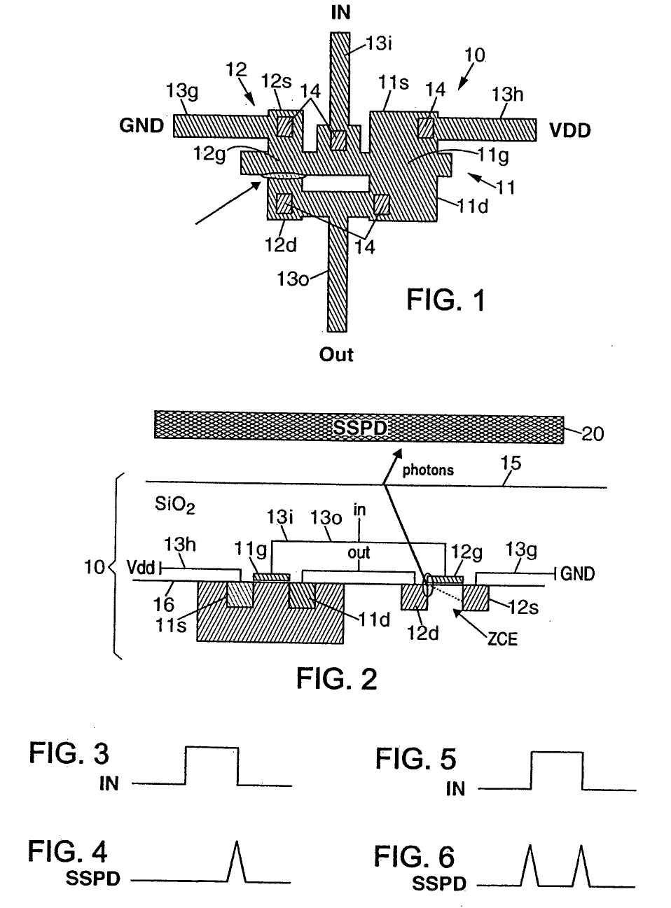

FIG. 1 shows a top view of an exemplary embodiment of an inverter using CMOS technology, called CMOS inverter for short. Such a CMOS inverter is formed on the surface of a doped silicon substrate of an integrated electronic circuit, according to conventional fabrication techniques.

The inverter 10 comprises a p-MOS transistor (MOS transistor of the p type) 11, and an n-MOS transistor 12. The transistor 11 comprises a source region 11s and a drain region 11d, or active regions, formed by implantation of dopant species under the surface of the substrate. In the same way, the n-MOS transistor 12 comprises a source region 12s and a drain region 12d, or active regions, formed by implantation of dopant species under the surface of the substrate. A region of polysilicon is deposited on the surface of the substrate in order to form the common gates of the transistors 11 and 12, with respective references 11g and 12g. The gate 11g straddles and partially covers the regions 11s and 11d. Similarly, the region 12g straddles and partially covers the regions 12s and 12d.

In a first metallization layer formed above the substrate, the inverter also comprises connections comprising a high voltage supply connection 13h, to which a positive supply potential VDD is applied, that is connected to the source region 11s of the p-MOS transistor 10. These connections also comprise a low voltage supply connection 13g, to which a ground potential GND is applied, and which is connected to the source region 12s of the n-MOS transistor 12. Also, an input connection 13i is connected to the common gate regions 11g and 12g, and receives a control signal IN for the inverter. Lastly, an output connection 13o is connected to the drain regions 11d and 12d of the transistors 11 and 12, respectively, in order to deliver an output signal OUT.

The connections 13h, 13g, 13i and 13o are metallic, for example copper or aluminum. Since the first metallization layer is isolated from the substrate by an insulator such as silicon dioxide (SiO₂), the connections are linked to the source, drain or gate regions underneath by conducting elements 14, called vias. In the example according to FIG. 1, the vias 14 are of rectangular cross section.

FIG. 2 shows a partial cross-sectional view of the inverter 10 in FIG. 1 which is employed as a switching element in a test structure according to the prior art.

The figure also allows an illustration of the principle of the photon measurement by means of an acquisition device 20, such as an SSPD sensor, disposed substantially above the switching element 10, on the front side 15 of the integrated circuit. For reasons of simplicity, the connections 13h, 13g, 13i and 13o are represented schematically by simple wires.

The connection 13i, at least, must be accessible from outside the integrated circuit, in order to be able to apply the control signal IN. In practice, the connection 13o does not also need to be accessible, since the switching element does not generally participate in the operation of the semiconductor device formed in the integrated circuit. Indeed, the switching element 10 is, in general, totally dedicated to the test function by photon measurement.

In a known manner, the p-MOS transistor 11 is formed within a cavity or well of n-doped silicon (‘n-well’) formed under the surface 16 of the circuit substrate. The minority carriers within the channel running between the active regions 11s and 11d of the p-MOS transistor 11 are holes. Conversely, the minority carriers within the channel running between the active regions 12s and 12d of the n-MOS transistor 12 are electrons.

The region in which the photon emission occurs is shown in an oval in FIGS. 1 and 2, this oval being indicated by an arrow in FIG. 1. In FIG. 2, the arrow indicates the path of the emitted photons.

More particularly, the photon emission takes place at the limit of the drain region of the n-MOS transistor 12, on the side of its gate region 12g. The emitted photon then passes through the metallization layers and exits from the front side 15 of the integrated circuit.

The operation of the test structure in FIG. 2 will now be explained with reference to the timing diagrams in FIGS. 3 and 4, in which a control signal IN of the inverter 10 and a signal SSPD, delivered by the acquisition device 20, are respectively shown.

When the signal IN is deactivated, in other words when a falling edge from the potential VDD to ground potential GND occurs in the signal IN, the n-MOS transistor 12 switches from the conducting state to the off state and the p-MOS transistor 11 switches from the off state to the conducting state, so as to make the output of the inverter go from ground potential GND to the potential VDD. At the instant of switching, in other words when the level of the control signal IN is equal to around VDD/2, a current briefly flows between the connections 13h and 13g. In the n-MOS transistor 12, the electrons (minority carriers) acquire more energy and move into a conduction band that is well above the minimum conduction band. It is said that they become hot electrons. The emission of a photon takes place when these hot electrons lose their energy and return to the silicon conduction band, at the end of the switching process.

By disposing the acquisition device 20 substantially directly above the switching element 10, this photon emission can then be detected. With a device of the SSPD sensor type, the detection is based on the formation of a ‘hot spot’ by thermalization of quasi-particles and on the suppression of the superconductivity owing to the diffusion of the hot spot. Other types of acquisition device may of course be envisaged, such as a Hamamatsu CCD camera, a Rockwell MCT camera, a PICA detector, an SiAPD sensor, or other device, depending on the wavelength of the emitted light.

As is shown by the curve in FIG. 4, the photon emission appears as a peak on the SSPD output signal of the acquisition device 20.

In FIGS. 5 and 6, the control signal IN of the switching element and the SSPD output signal of a photon acquisition device, respectively, are shown in the case where, in place of an inverter as shown in FIGS. 1 and 2, the switching element is a buffer circuit, in other words a circuit formed from two inverters in series. In this case, the emission of a photon is detected (peak in the SSPD signal) on both the rising edge and on the falling edge of the control signal IN, given that the n-MOS transistors of each inverter respectively switch on either the rising edge of the signal IN (for the second inverter), or on the falling edge of the signal IN (for the first inverter).

In another embodiment, the switching element can be a simple n-MOS transistor. However, an n-MOS transistor that is part of a CMOS inverter is preferred, whose quiescent current is zero (the CMOS inverter has a current between the power supply connections 13h and 13g flowing through it only at the instant of switching).

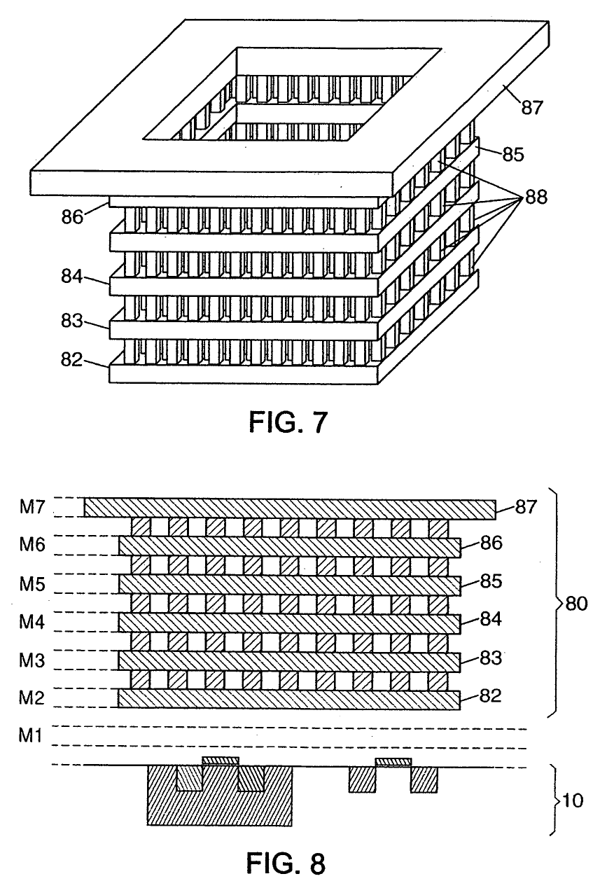

FIG. 7 and FIG. 8 show, in a three-dimensional view and in a top cross-sectional view, respectively, a structure called a tunnel or chimney, which is designed to channel the photons emitted by the switching element 10 towards the front side 15 of the integrated circuit. In the embodiment shown, the tunnel comprises a stack of metal rings 82-87 with adjacent rings being connected by vias 88.

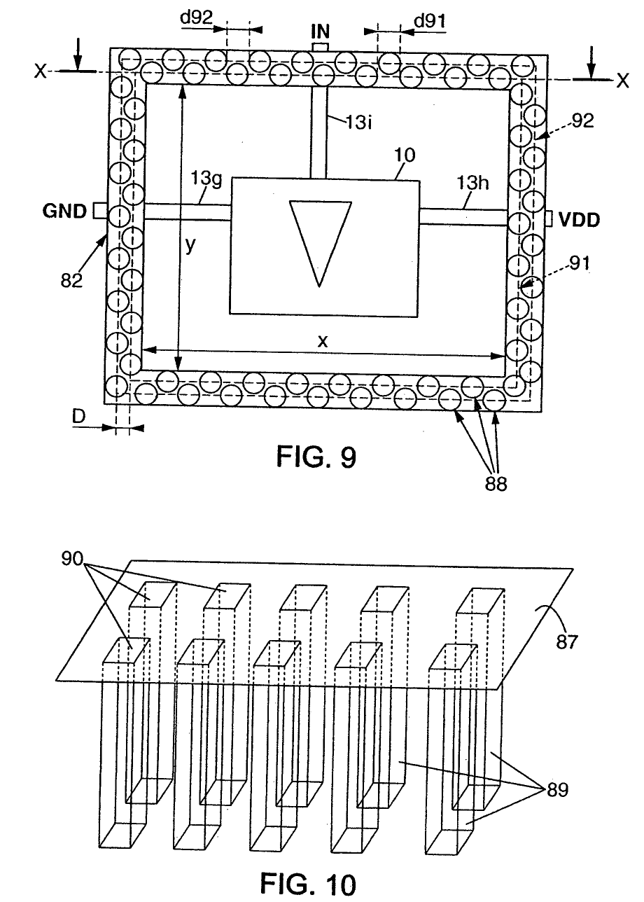

In FIG. 8, the tunnel 80 is shown in cross section according to an axis X-X shown in FIG. 9 (see below), and the switching element 10 is shown in a conventional cross-sectional plane.

Each metal ring is fabricated within a given metallization layer, here respectively denoted M2-M7, the ring furthest away from the switching element (in other words the furthest away from the substrate) being formed within the surface metallization layer, here layer M7. By ‘surface metallization layer’ is meant the layer that is highest, in other words the closest to the front side of the integrated circuit from which it is separated only by a thin insulating layer.

The lowest metallization layer, here denoted M1, in other words the layer situated just above the circuit substrate, is for example used to form the connections 13h, 13g, 13i, and 13o. For reasons of simplicity, these connections in the metallization layer M1 are not shown in FIG. 8.

The metal rings 82-87 are substantially concentric, with their axes substantially orthogonal to the substrate surface.

The density of the vias 88 is high and their distribution is uniform, such that they act as a screen preventing the photons from escaping from the tunnel between two adjacent stacked metal rings.

One advantageous embodiment is illustrated by the circuit diagram in FIG. 9, in which the test structure is shown in a top view in a plane situated between the plane of the metal ring 82, which is the closest to the substrate, and that of the ring 83. The inner dimensions of the metal ring 82, denoted x and y, are for example of the order of 2 to 4 μm.

In this embodiment, the vias connecting two adjacent stacked metal rings comprise a first group of vias disposed around an inner ring 91, and a second group of vias disposed around an outer ring 92. The vias of the ring 91 are laterally spaced one from the next by a distance d91 that is less than a corresponding characteristic dimension of the cross section of the vias in a plane orthogonal to the axis of the tunnel (in other words the axis perpendicular to the plane of FIG. 9).

In the example shown in FIG. 9, the vias have a circular cross section. A ‘corresponding characteristic dimension’, in the above sense, is then the diameter of the cross section of the vias. For example, the diameter of the vias is around 0.2 μm (or 200 nm).

When the vias have a square cross section, a ‘corresponding characteristic dimension’ is then the side of the said square. When the vias have a rectangular cross section, a ‘corresponding characteristic dimension’ is the length of the short or of the long side of the rectangle which is measured along the alignment direction of the vias of the ring 91, which direction is shown by a dashed line in FIG. 9.

The same arrangements as above can be advantageously applied to the lateral distance d92 separating the adjacent vias of the outer ring 92.

In addition, the vias of the inner ring 91 and the vias of the outer ring 92 are disposed staggered with respect to one other. In this manner, a good optical isolation of the interior of the tunnel with respect to the exterior of the tunnel (in both possible directions) is obtained, in the sense that a photon is not able to pass along a direct path between the vias.

In one embodiment, the distance D between the alignment direction of the centers of the vias of the inner ring and that of the centers of the vias of the outer ring is of the order of a corresponding characteristic dimension (in the above sense) of the cross section of the said vias in a plane orthogonal to the axis of the tunnel. In other words, the radial distance between the vias of the respective rings 91 and 92 is reduced to the minimum (the distance D can also be called the radial distance between the centers of the vias of the inner ring and the centers of the vias of the outer ring). In this way, the possibility of a photon making use of reflection/diffraction phenomena on the via walls in order to pass between the two rings of vias is minimized.

In FIG. 9, the axis X-X corresponding to the cross-sectional plane of the tunnel 80 in FIG. 8 passes through the center of the vias of the inner ring 91.

In the embodiment shown in the figures, the metal rings 82-87 have a square shape. Other shapes, notably circles or rectangles, may obviously be envisaged.

The ring 87 formed within the surface metallization layer M7 can protrude, in the plane of the said layer M7, with respect to the projection of the other rings in the same plane. Indeed, the interior dimensions of the metal rings are determined such that the tunnel 80 can collect the photons emitted by the switching element (the cross section of the tunnel 80 therefore corresponding substantially to the size of this element), but the last ring can have exterior sides that are larger than those of the other rings so as to act as a screen from the evanescent photons that could otherwise come into contact with the active surface of the acquisition device 20 and thus interfere with the measurement. In particular, the exterior dimensions of the last metal ring 87 can advantageously correspond to the dimensions of the said active surface.

FIG. 10 shows (partially) an exemplary embodiment of a multiple tunnel structure that is suitable for an integrated electronic circuit having a plurality of test structures such as that described hereinabove. In this example, a plurality of tunnels 89 is formed directly above respective switching elements (not shown). These tunnels 89 have the metal ring 87 in common which is formed within the surface metallization layer (the other metal rings are not shown). In other words, the ring 87 is a metal plane that is common to the tunnels 89, and in which openings 90 are respectively formed for each tunnel.

All of the above U.S. patents, U.S. patent application publications, U.S. patent applications, foreign patents, foreign patent applications and non-patent publications referred to in this specification and/or listed in the Application Data Sheet, are incorporated herein by reference, in their entirety.

From the foregoing it will be appreciated that, although specific embodiments of the invention have been described herein for purposes of illustration, various modifications may be made without deviating from the spirit and scope of the invention. Accordingly, the invention is not limited except as by the appended claims.

1. A test structure for integrated electronic circuits, comprising:
a substantially planar substrate;
a switching element formed on a surface of the substrate; and
a tunnel element formed above the switching element and designed to channel photons emitted by the switching element, the said tunnel element comprising a stack of metal rings formed within respective metallization layers, adjacent rings being connected to one another by vias, the vias having a density and the distribution such that the vias provide a screen preventing the photons from escaping from the tunnel element between two adjacent metal rings of the stack.

2. The test structure according to claim 1, wherein the metal rings are substantially concentric, with axes substantially orthogonal to the substrate surface.

3. The test structure according to claim 1, wherein:
the vias connecting the two adjacent metal rings comprises a first group of vias disposed around an inner ring and a second group of vias disposed around an outer ring;
the vias of the inner ring are laterally spaced from each other by a distance that is less than a corresponding characteristic dimension of a cross section of the said vias in a plane orthogonal to an axis of the tunnel element;
the vias of the outer ring are laterally spaced from each other by a distance that is less than a corresponding characteristic dimension of the cross section of the said vias in a plane orthogonal to the axis of the tunnel element; and
the vias of the inner ring and the vias of the outer ring are disposed staggered with respect to one other.

4. The test structure according to claim 3, wherein a distance between an inner line extending through central axes of the vias of the inner ring and an outer line extending through central axes of the vias of the outer ring is of an order of a corresponding characteristic dimension of the cross section of the vias in a plane orthogonal to the axis of the tunnel element.

5. The test structure according to claim 1, wherein the metal ring of the stack that is furthest from the switch element laterally protrudes with respect to the metal rings of the stack that are closer to the switching element.

6. The test structure according to claim 1, wherein the metal rings each have a square-shaped cross section.

7. An integrated electronic circuit, comprising:
a substantially planar substrate; and
a first test structure that includes:
a first switching element formed on a surface of the substrate; and
a first tunnel formed between the switching element and a front side of the integrated circuit and designed to channel photons emitted by the switching element toward the front side, the first tunnel being laterally defined by a first stack of metallization layers, wherein adjacent metallization layers are connected to one another by vias having a density and distribution such that the vias provide a screen preventing the photons from escaping from the first tunnel between two adjacent metallization layers of the first stack.

8. The integrated electronic circuit according to claim 7, further comprising:
a second test structure including:
a second switching element formed on the surface of the substrate; and
a second tunnel formed between the second switching element and the front side of the integrated circuit and designed to channel photons emitted by the second switching element toward the front side, the second tunnel being laterally defined by a second stack of metallization layers, wherein adjacent metallization layers of the second stack are connected to one another by vias, the vias of the second tunnel having a density and distribution such that the vias provide a screen preventing the photons from escaping from the second tunnel between two adjacent metal metallization layers of the second stack, wherein a surface metallization layer is a common metal plane in which openings are respectively formed for each of the first and second tunnels.

9. The test structure of claim 8, wherein the metallization layers of the first and second stacks are shaped as metal rings.

10. The test structure of claim 9, wherein the metal rings have square-shaped cross sections.

11. A test structure for testing a integrated electronic circuit, the test structure comprising:
a switching element implanted on an area of the electronic circuit and able to emit photons during switching;
a tunnel member having an elongated ring wall defining an interior passageway, the tunnel element protruding from a surface of the switching element in such a way that the interior passageway is in communication with the switching element for channeling the photons emitted thereby, wherein the elongated ring wall is structured to prevent the photons from laterally escaping from the interior passageway and evanescent photons from laterally entering the tunnel member from outside of the tunnel member.

12. The test structure according to claim 1 1, wherein the tunnel member comprises a stack of adjacent metal rings connected to one other by a plurality of vias, the metal rings and the vias defining the elongated ring wall of the tunnel member, the stack extending from a surface of the integrated circuit.

13. The test structure according to claim 12, wherein the switching element is overlaid by a plurality of metallization layers of the integrated circuit.

14. The test structure according to claim 13, wherein each of the adjacent metal rings of the tunnel member is included within a respective one of the metallization layers of the integrated circuit.

15. The test structure according to claim 12, wherein the vias connecting two adjacent metal rings of the stack comprise a first group of vias arranged in an inner annular configuration and a second group of vias arranged in an outer annular configuration.

16. The test structure according to claim 15, wherein:
the vias of the first group are laterally spaced from each other by a distance that is less than a corresponding characteristic dimension of a cross section of the vias in a plane orthogonal to a longitudinal axis of the tunnel member;
the vias of the second group are laterally spaced from each other by a distance that is less than a corresponding characteristic dimension of a cross section of the vias in a plane orthogonal to a longitudinal axis of the tunnel member; and
the vias of the first group and the vias of the second group are staggered with respect to one another.

17. The test structure according to claim 12, wherein the stack of adjacent metal rings is arranged substantially orthogonal to the surface of the integrated electronic circuit.

18. The test structure according to claim 12, wherein the stack of adjacent metal rings extends along a tilted axis with respect to a perpendicular to the surface of the integrated electronic circuit.

19. The test structure according to claim 12, wherein the metal rings each have a square-shaped cross section.

20. An integrated electronic device comprising:
an integrated electronic circuit having a substantially planar substrate overlaid with a plurality of metallization layers;
a switching element formed on the substrate of the integrated electronic circuit and able to emit photons during switching for testing the integrated electronic circuit; and
a tunnel member having an elongated ring wall defining an interior passageway, the tunnel member protruding from a surface of the switching element through the plurality of metallization layers of the integrated electronic circuit,
wherein the interior passageway is in communication with the switching element for channeling the photons emitted thereby toward a side of the integrated circuit, and wherein the elongated ring wall is designed to prevent the photons from laterally escaping from the interior passageway and evanescent photons from laterally entering the tunnel member from outside.

21. The electronic device according to claim 20, wherein the switching element is one of a plurality of adjacent switching elements and the tunnel element is one of a plurality of adjacent tunnel members, wherein each of the tunnel member is protruding from a surface of a respective one of the switching elements.

22. The electronic device according to claim 20, wherein the tunnel member comprises a stack of adjacent metal rings connected to one other by a plurality of vias, the metal rings and the vias defining the elongated ring wall of the tunnel member, the stack extending from a surface of the integrated circuit.
